(19) United States
(12) Patent Application Publication
(10) Pub. No.: US 2026/0206575 A1
(43) Pub. Date: Jul. 16, 2026

(54) SEMICONDUCTOR STRUCTURE AND METHOD FOR FORMING THE SAME

(71) Applicant: Powerchip Semiconductor Manufacturing Corporation, Hsinchu (TW)

(72) Inventors: Shih-Wei Lo, Hsinchu (TW); Tzung-Bin Huang, Hsinchu (TW)

(73) Assignee: Powerchip Semiconductor Manufacturing Corporation, Hsinchu (TW)

(21) Appl. No.: 19/069,163

(22) Filed: Mar. 3, 2025

(30) Foreign Application Priority Data
Jan. 15, 2025 (TW) 114101605

(51) Int. Cl. H01L 23/528; H01L 21/768; H01L 23/48

(52) U.S. Cl. CPC H10W 20/435; H10W 20/023; H10W 20/056; H10W 20/081; H10W 20/20

(57) ABSTRACT

The present disclosure provides a semiconductor structure and a method for forming the same. The semiconductor structure includes a conductive structure penetrating an interconnection structure and a substrate where the interconnection structure is disposed thereon. The conductive structure includes a through-conductive via penetrating the interconnection structure and the substrate in a vertical direction and a ring-shaped conductive via disposed in the interconnection structure and surrounding the through-conductive via. The interconnection structure includes a conductive layer configured on the ring-shaped conductive via and being directly in contact with a top surface of the ring-shaped conductive via.

### CROSS-REFERENCE TO RELATED APPLICATION

This application claims the priority benefit of Taiwan application serial no. 114101605, filed on Jan. 15, 2025. The entirety of the above-mentioned patent application is hereby incorporated by reference herein and made a part of this specification.

### BACKGROUND

### Technical Field

The present invention relates to a semiconductor structure and a method of forming the same.

### Description of Related Art

Three-dimensional (3D) wafer vertical stack technology seeks to achieve the long-awaited goal of vertically stacking many layers of active components (e.g., processors, programmable components, memory components, or the like) inside a single chip to shorten average wire lengths, thereby reducing interconnect RC delay and increasing system performance. In some embodiments, through substrate vias (TSVs) may be used to connect the active components formed in the wafers stacked in the vertical direction. For example, the electrical connection paths between different wafers can be provided by the TSVs penetrating through these wafers, but this will require a plurality of TSV layers with TSVs formed therein to connect different wiring layers to provide the above electrical connection paths. However, as the sizes of the electronic devices continue to shrink, the fabrication of TSV layers connecting these wafers will face various challenges (e.g., the stability of the electrical connections between each TSV layer and each wiring layer may not meet the current or future requirements).

To address the above challenges, a technique using a single TSV to connect a plurality wiring layers has been proposed (also known as one-step TSV), which is formed to have a desired electrical connection path by making the single TSV penetrating these wiring layers. However, it will reduce the contact areas between the one-step TSV and the wiring layers, and the diameter of the one-step TSV will gradually decrease as the number of wiring layers penetrated by the one-step TSV increases. Accordingly, the contact area will gradually decrease as the number of wiring layers penetrated by the one-step TSV increases. Therefore, in order to ensure the stability of the electrical connection path, it will be difficult to reduce the diameter and pitch of the one-step TSV.

### SUMMARY

The present invention provides a semiconductor structure and a method for forming the same in which the conductive structure is designed to include a through conductive via penetrating through a substrate and an interconnection structure in the vertical direction, and a ring-shaped conductive via disposed in the interconnection structure and surrounding the through conductive via. As such, the contact area between the through conductive via and the conductive layer in the interconnection structure can be increased through the ring-shaped conductive via, and thereby reducing the contact resistance and having a promising stability. On the other hand, when the semiconductor structure is applied to a one-step TSV, the stability of the desired electrical connection path is ensured while the diameter and pitch of the one-step TSV are reduced.

An embodiment of the present invention provides a semiconductor structure including conductive structure penetrating through an interconnection structure and a substrate on which the interconnection structure is disposed. The conductive structure includes a through conductive via penetrating through the interconnection structure and the substrate in a vertical direction, and a ring-shaped conductive via disposed in the interconnection structure and surrounding the through conductive via. The interconnection structure includes a conductive layer disposed on the ring-shaped conductive via and being directly in contact with a top surface of the ring-shaped conductive via.

In some embodiments, a bottom surface of the ring-shaped conductive via is directly in contact with a dielectric layer in the interconnection structure.

In some embodiments, the ring-shaped conductive via is directly in contact with the through conductive via.

In some embodiments, the ring-shaped conductive via and the conductive layer are respectively a via portion and a wiring portion of an entire conductive layer.

In some embodiments, the through conductive via includes a lower portion surrounded by the ring-shaped conductive via and the conductive layer, and an upper portion on the conductive layer, wherein a width of the upper portion in a horizontal direction is greater than a width of the lower portion in the horizontal direction.

An embodiment of the present invention provides a method of forming a semiconductor structure, which includes following steps. A conductive structure is formed, wherein the conductive structure penetrates through an interconnection structure and a substrate on which the interconnection structure is formed. The conductive structure includes a through conductive via penetrating through the substrate and the interconnection structure in a vertical direction, and a ring-shaped conductive via formed in the interconnection structure and surrounding the through conductive via. The interconnection structure includes a conductive layer formed on the ring-shaped conductive via and being directly in contact with a top surface of the ring-shaped conductive via.

In some embodiments, a step of forming the ring-shaped conductive via includes the following steps. A stacked layer is formed on the substrate, wherein the stacked layer includes a plurality of first dielectric material layers and a plurality of second dielectric material layers that are stacked alternatively, and the second dielectric material layers are between the first dielectric material layers. A ring via hole is formed in the stacked layer, wherein the ring via hole penetrates through a first layer among the plurality of first dielectric material layers and a second layer among the plurality of first dielectric material layer and above the first layer. A trench is formed in the second layer communicating with the ring via hole. A conductive material is filled into the ring via hole and the trench to form the ring-shaped conductive via and the conductive layer.

In some embodiments, a step of forming the through conductive via includes following steps. An insulation layer is formed on the stacked layer after the ring-shaped conductive via is formed. A through hole is formed to penetrate the insulation layer, a portion of the stacked layer surrounded by the ring-shaped conductive via, and the substrate, wherein a sidewall of the ring-shaped conductive via is exposed by the through hole. The through conductive via is formed in the through hole.

In some embodiments, a step of forming the ring-shaped conductive via includes following steps. A dielectric material layer is formed on the substrate. A ring via hole is formed in the dielectric material layer. The ring-shaped conductive via is formed in the ring via hole.

In some embodiments, a step of forming the through conductive via includes following steps. A conductive material layer, covering the ring-shaped conductive via, is formed on the dielectric material layer. The conductive material layer is patterned to form the conductive layer, wherein the conductive layer includes an opening exposing a portion of the dielectric material layer surrounded by the ring-shaped conductive via. An insulation layer, covering the conductive layer and filling the opening, is formed on the dielectric material layer. A through hole is formed to penetrate the insulation layer, the portion of the dielectric material layer surrounded by the ring-shaped conductive via, and the substrate, wherein a sidewall of the ring-shaped conductive via is exposed by the through hole. The through conductive via is formed in the through hole.

Based on the above, in the aforementioned semiconductor structure and method for forming the same, the conductive structure is designed to include the through conductive via penetrating through the substrate and the interconnection structure in the vertical direction, and the ring-shaped conductive via disposed in the interconnection structure and surrounding the through conductive via. As such, the contact area between the through conductive via and the conductive layer in the interconnection structure can be increased through the ring-shaped conductive via, and thereby reducing the contact resistance and having a promising stability.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1A to FIG. 9B are schematic views of a method for forming a semiconductor structure according to an embodiment of the present invention.

FIG. 10A to FIG. 18B are schematic cross-sectional views of a method for forming a semiconductor structure according to another embodiment of the present invention.

### DESCRIPTION OF THE EMBODIMENTS

Reference is made to the figures of this embodiment to more comprehensively elucidate the present invention. However, the present invention may be embodied in various different forms and should not be limited to the embodiments described herein. The thicknesses of layers and regions in the figures are exaggerated for clarity. The same or similar reference numbers indicate the same or similar components, which will not be redundantly described in the following paragraphs.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

It will be understood that when an element is referred to as being “on” or “connected” to another element, it may be directly on or connected to the other element or intervening elements may be present. If an element is referred to as being “directly on” or “directly connected” to another element, there are no intervening elements present. As used herein, “connection” may refer to both physical and/or electrical connections, and “electrical connection” or “coupling” may refer to the presence of other elements between two elements. As used herein, “electrical connection” may refer to the concept including a physical connection (e.g., wired connection) and a physical disconnection (e.g., wireless connection).

As used herein, “about”, “approximately” or “substantially” includes the values as mentioned and the average values within the range of acceptable deviations that can be determined by those of ordinary skill in the art. Consider to the specific amount of errors related to the measurements (i.e., the limitations of the measurement system), the meaning of “about” may be, for example, referred to a value within one or more standard deviations of the value, or within ±30%, ±20%, ±10%, ±5%. Furthermore, the “about”, “approximate” or “substantially” used herein may be based on the optical property, etching property or other properties to select a more acceptable deviation range or standard deviation, but may not apply one standard deviation to all properties.

The terms used herein are used to merely describe exemplary embodiments and are not used to limit the present disclosure. In this case, unless indicated in the context specifically, otherwise the singular forms include the plural forms.

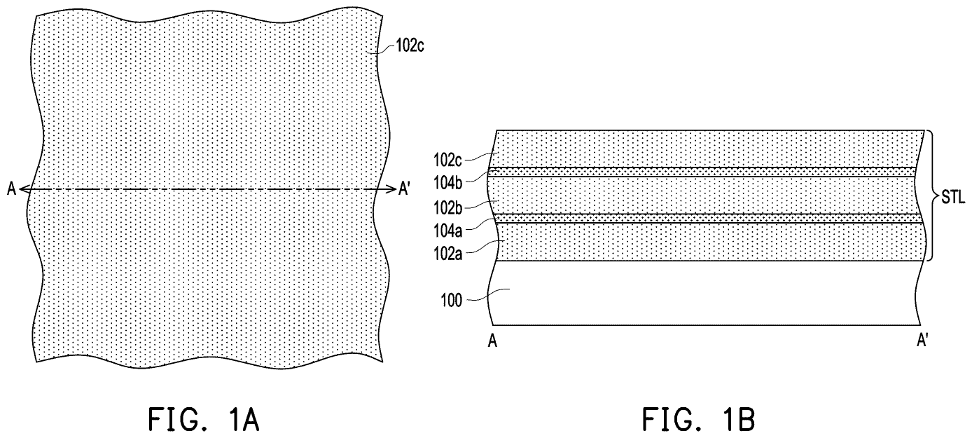

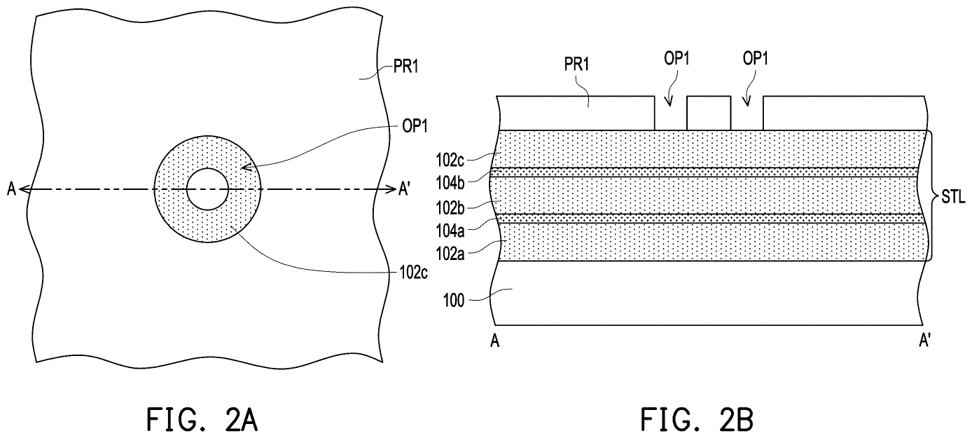

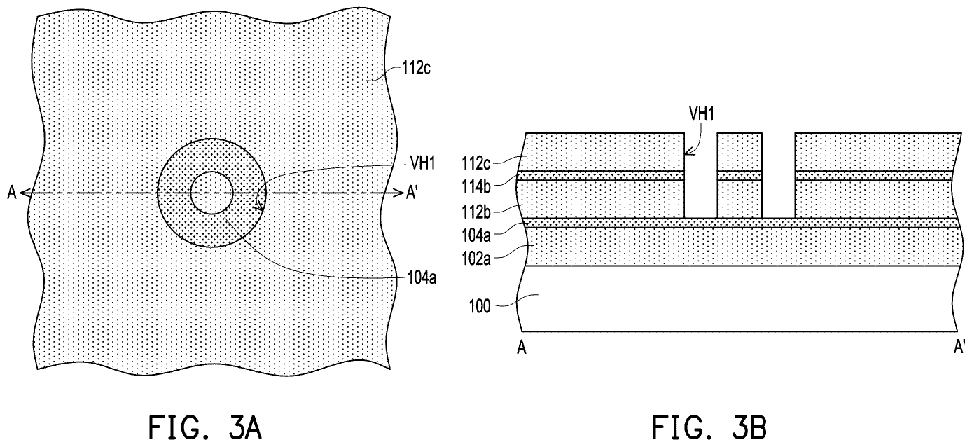

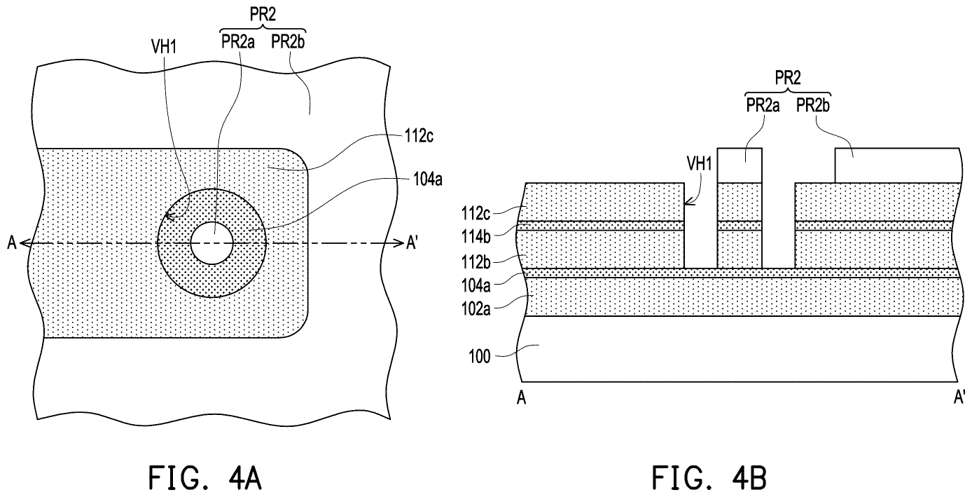

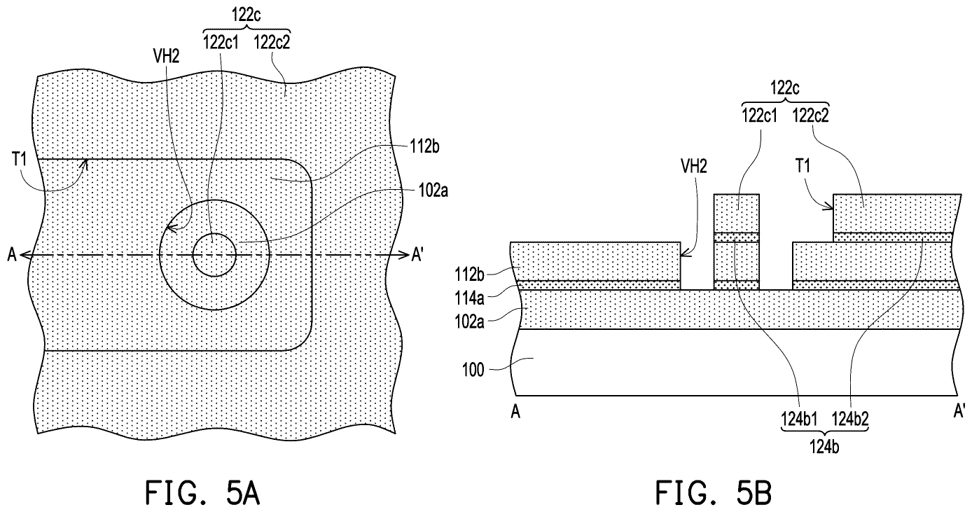

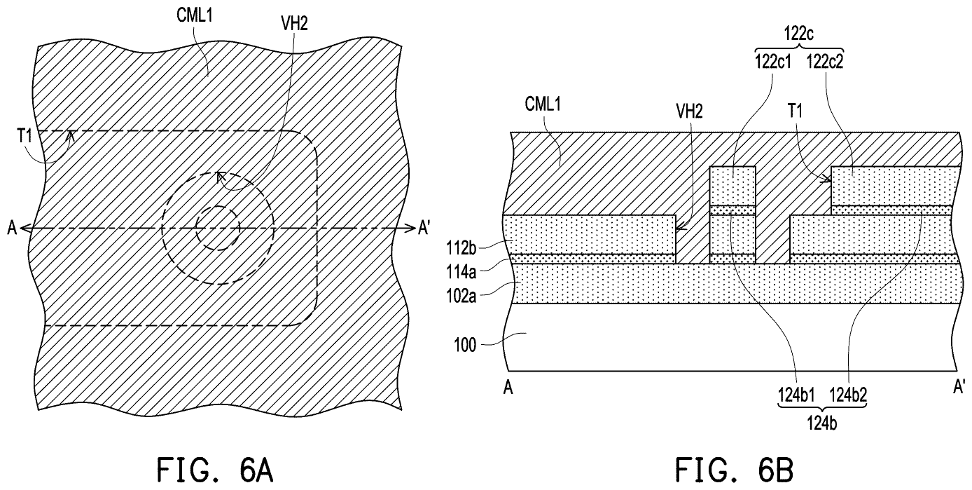

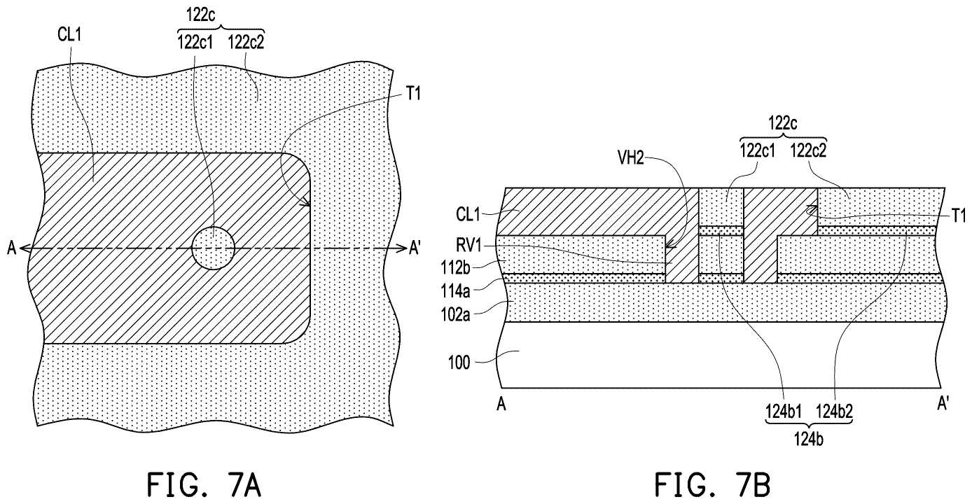

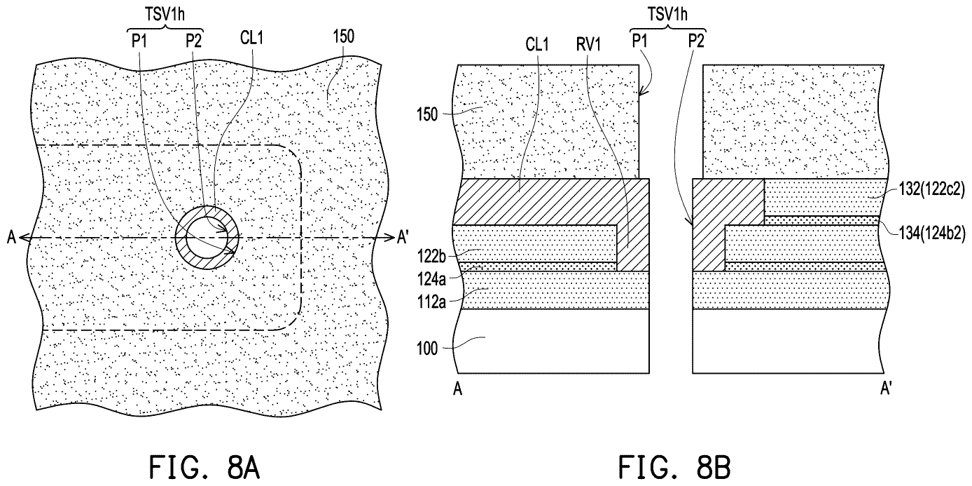

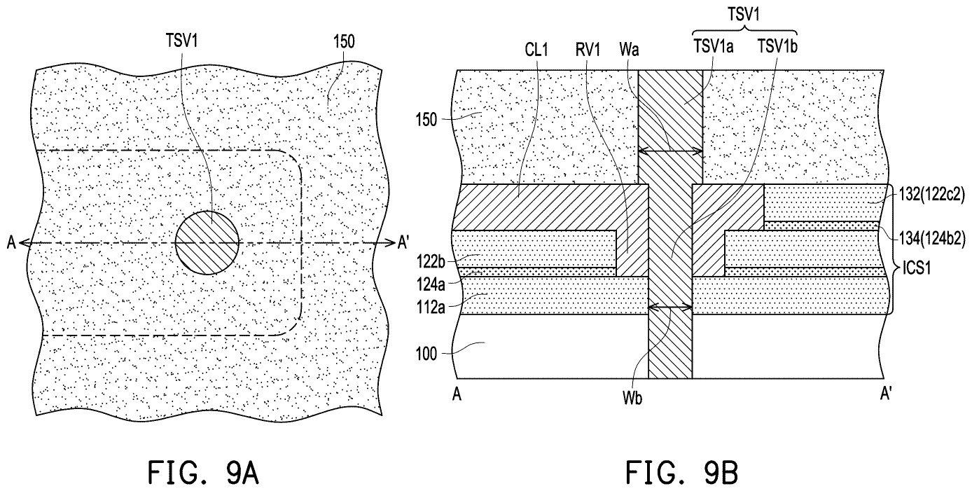

FIG. 1A to FIG. 9B are schematic views of a method for forming a semiconductor structure according to an embodiment of the present invention. FIG. 1A, FIG. 2A, FIG. 3A, FIG. 4A, FIG. 5A, FIG. 6A, FIG. 7A, FIG. 8A, and FIG. 9A are schematic top views of a method for forming a semiconductor structure according to an embodiment of the present invention, and FIG. 1B, FIG. 2B, FIG. 3B, FIG. 4B, FIG. 5B, FIG. 6B, FIG. 7B, FIG. 8B, and FIG. 9B are schematic cross-sectional views taken along line A-A′ in FIG. 1A, FIG. 2A, FIG. 3A, FIG. 4A, FIG. 5A, FIG. 6A, FIG. 7A, FIG. 8A, and FIG. 9A, respectively.

The method for forming a semiconductor structure includes a step of forming a conductive structure penetrating through an interconnection structure and a substrate on which the interconnection structure is formed. In some embodiments, the conductive structure may be formed through the following steps.

Firstly, referring to FIG. 1A and FIG. 1B, a substrate 100 is provided. The substrate 100 may include a semiconductor substrate or a semiconductor-on-insulator (SOI) substrate, and a device layer formed on the semiconductor substrate or the SOI substrate.

The semiconductor materials in the semiconductor substrate or in the SOI substrate may include an element semiconductor, an alloy semiconductor, or a compound semiconductor. For example, the element semiconductor may include Si or Ge. The alloy semiconductor may include SiGe, SiGeC, or the like. The compound semiconductor may include SiC, III-V semiconductor materials, or II-VI semiconductor materials. The III-V semiconductor materials may include GaN, GaP, GaAs, AlN, AlP, AlAs, InN, InP, InAs, GaNP, GaNAs, GaPAs, AlNP, AlNAs, AlPAs, InNP, InNAs, InPAs, GaAlNP, GaAlNAs, GaAlPAs, GaInNP, GaInNAs, GaInPAs, InAlNP, InAlNAs, or InAlPAs. The II-VI semiconductor materials may include CdS, CdSe, CdTe, ZnS, ZnSe, ZnTe, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, or HgZnSTe. The semiconductor material may be doped with a dopant of a first conductivity type or a dopant of a second conductivity type complementary to the first conductivity type. For example, the first conductivity type may be p-type, whereas the second conductivity type may be n-type.

The device layer may include active devices such as N-type metal-oxide-semiconductor (NMOS), P-type metal-oxide-semiconductor (PMOS), or complementary metal-oxide-semiconductor (CMOS).

Next, a stacked layer STL is formed on the substrate 100. The stacked layer STL may include a plurality of first dielectric material layers 102a, 102b, 102c and a plurality of second dielectric material layers 104a, 104b that are stacked alternatively, wherein the second dielectric material layers 104a, 104b are between the first dielectric material layers 102a, 102b, 102c. In some embodiments, the material of the first dielectric material layers 102a, 102b, 102c may be different from the material of the second dielectric material layers 104a, 104b. For example, the first dielectric material layers 102a, 102b, 102c may include oxides such as silicon oxide. The second dielectric material layers 104a, 104b may include nitrides such as silicon nitride.

Then, a ring via hole (e.g., the ring via hole VH1 shown in FIG. 3A and FIG. 3B) is formed in the stacked layer STL, wherein the ring via hole penetrates a first layer (e.g., the first dielectric material layer 102b) among the plurality of first dielectric material layers 102a, 102b, 102c and a second layer (e.g., the first dielectric material layer 102c) among the plurality of first dielectric material layers 102a, 102b, 102c and above the first layer. In some embodiments, the ring via hole may be formed through the following steps. Firstly, referring to FIG. 2A and FIG. 2B, a mask pattern PR1 having a ring-shaped opening OP1 is formed on the stacked layer STL. In some embodiments, the mask pattern PR1 may include a photoresist pattern. Next, referring to FIG. 2A and FIG. 2B and FIG. 3A and FIG. 3B, the first dielectric material layer 102c exposed by the ring-shaped opening OP1 and the second dielectric material layer 104b and the first dielectric material layer 102b thereunder are removed to form a first dielectric material layer 112c, a second dielectric material layer 114b, a first dielectric material layer 112b, and the ring via hole VH1 exposing the second dielectric material layer 104a. In this embodiment, the second dielectric material layer 104a may serve as an etching stop layer for forming the ring via hole VH1. After that, the mask pattern PR1 is removed after the ring via hole VH1 is formed.

After that, a trench (e.g., the trench T1 shown in FIG. 5A and FIG. 5B) communicating with the ring via hole VH1 is formed in the second layer (e.g., the first dielectric material layer 102c or the first dielectric material layer 112c). In some embodiments, the trench may be formed through the following steps. Firstly, referring to FIG. 4A and FIG. 4B, a mask pattern PR2 is formed on the first dielectric material layer 112c. The mask pattern PR2 may include a first portion PR2a and a second portion PR2b. The first portion PR2a covers the portion of the first dielectric material layer 112c surrounded by the ring via hole VH1. The second portion PR2b defines the pattern of the trench to be formed subsequently (e.g., the pattern of the trench T1 shown in FIG. 5A). In some embodiments, the mask pattern PR2 may include a photoresist pattern. Next, referring to FIG. 4A and FIG. 4B and FIG. 5A and FIG. 5B, a portion of the first dielectric material layer 112c exposed by the mask pattern PR2 and the second dielectric material layer 114b under the portion thereof are removed to form a first dielectric material layer 122c, a second dielectric material layer 124b and the trench T1. In some embodiments, during the step of removing the second dielectric material layer 114b, a portion of the second dielectric material layer 104a exposed by the ring via hole VH1 is also removed to form a second dielectric material layer 114a. Afterwards, the mask pattern PR2 is removed after the trench T1 is formed.

In some embodiments, as shown in FIG. 5A and FIG. 5B, a first portion 122c1 of the first dielectric material layer 122c and a first portion 124b1 of the second dielectric material layer 124b cover the portions of the first dielectric material layer 112b and the second dielectric material layer 114a surrounded by the ring via hole VH2. The sidewalls of a second portion 122c2 of the first dielectric material layer 122c and a second portion 124b2 of the second dielectric material layer 124b define the profile of the trench T1.

Next, referring to FIG. 5A and FIG. 5B and FIG. 6A and FIG. 6B, a conductive material CML1 is filled into the ring via hole VH2 and the trench T1. In some embodiments, the conductive material CML1 may include conductive materials such as metals or metal alloys. The metals and metal alloys may be, for example, Cu, Al, Ti, Ta, W, Pt, Cr, Mo or alloys thereof. Subsequently, referring to FIG. 6A and FIG. 6B and FIG. 7A and FIG. 7B, a planarization process such as a chemical mechanical polishing (CMP) is performed on the conductive material CML1 to form a conductive layer CL1 and a ring-shaped conductive via RV1.

After that, referring to FIG. 7A and FIG. 7B and FIG. 8A and FIG. 8B, after forming the conductive layer CL1 and the ring-shaped conductive via RV1, an insulation layer 150 is formed on the first dielectric material layer 122c. In some embodiments, the insulation layer 150 may include oxide, such as tetraethyl orthosilicate (TEOS), borophosphosilicate glass (BPSG), oxide formed by high density plasma (HDP), undoped silicate glass (USG), phosphosilicate glass (PSG), oxide formed by spin-on method such as spin on glass (SOG) and spin on dielectric (SOD), or oxide formed by high aspect ratio process (HARP).

Next, a through hole TSV1h penetrating the insulation layer 150, the first portion 122c1 of the first dielectric material layer 122c, the first portion 124b1 of the second dielectric material layer 124b, the portions of the first dielectric material layer 112b and the second dielectric material layer 114a surrounded by the ring-shaped conductive via RV1, the first dielectric material layer 102a, and the substrate 100 beneath these portions is formed. The through hole TSV1h may include a first portion P1 formed in the insulation layer 150 and a second portion P2 exposing the sidewalls of the ring-shaped conductive via RV1. The second portion P2 of the through hole TSV1h is formed by removing the first portion 122c1 of the first dielectric material layer 122c and the first portion 124b1 of the second dielectric material layer 124b as well as the first dielectric material layer 112b, the second dielectric material layer 114a, the first dielectric material layer 102a, and the substrate 100 thereunder.

Afterwards, a through conductive via TSV1 is formed in the through hole TSV1h. As a result, the through conductive via TSV1 penetrates the substrate 100 and the interconnection structure ICS1 in the vertical direction, and the ring-shaped conductive via RV1 is formed in the interconnection structure ICS1 surrounding the through conductive via TSV1. This may increase the contact area between the through conductive via TSV1 and the conductive layer CL1 in the interconnection structure ICS1 through the ring-shaped conductive via RV1, thereby reducing the contact resistance and providing a promising stability. On the other hand, when the semiconductor structure is applied to a one-step TSV (e.g., when two ends of the through conductive via TSV1 are electrically connected to other wafers), the stability of the desired electrical connection path is ensured while the diameter and pitch of the one-step TSV are reduced. In some embodiments, the through conductive via TSV1 may include conductive materials such as metals or metal alloys. The metal and metal alloy may be, for example, Cu, Al, Ti, Ta, W, Pt, Cr, Mo, or alloys thereof.

In some embodiments, as shown in FIG. 9B, the interconnection structure ICS1 may include first dielectric material layers 112a, 122b, 132 and second dielectric material layers 124a, 134 alternatively disposed on the substrate 100, wherein the second dielectric material layers 124a, 134 are disposed between the first dielectric material layers 112a, 122b, 132. In some embodiments, the conductive layer CL1 may be formed in the first dielectric material layer 132 and the second dielectric material layer 134 of the interconnection structure ICS1, while the ring-shaped conductive via RV1 may be formed in the first dielectric material layer 122b and the second dielectric material layer 124a of the interconnection structure ICS1.

Hereinafter, a semiconductor structure according to an embodiment of the disclosure will be illustrated with reference to FIG. 9A and FIG. 9B. The semiconductor structure of the embodiment may be formed by the method described above, but is not limited thereto.

Referring to FIG. 9A and FIG. 9B, the semiconductor structure may include a conductive structure penetrating the interconnection structure ICS1 and the substrate 100 on which the interconnection structure ICS1 is disposed, wherein the conductive structure may include a through conductive via TSV1 penetrating the interconnection structure ICS1 and the substrate 100 in the vertical direction, and a ring-shaped conductive via RV1 disposed in the interconnection structure ICS1 and surrounding the through conductive via TSV1. The interconnection structure ICS1 may include a conductive layer CL1 disposed above the ring-shaped conductive via RV1 and being directly in contact with a top surface of the ring-shaped conductive via RV1.

In some embodiments, a bottom surface of the ring-shaped conductive via RV1 may be directly in contact with a dielectric layer (e.g., the first dielectric material layer 112a) in the interconnection structure ICS1. In some embodiments, the ring-shaped conductive via RV1 is directly in contact with the through conductive via TSV1. In some embodiments, the ring-shaped conductive via RV1 and the conductive layer CL1 may be a via portion and a wiring portion of an entire conductive layer, respectively. In other words, the ring-shaped conductive via RV1 and the conductive layer CL1 may be formed simultaneously in the same process, that is, the interface where the ring-shaped conductive via RV1 and the conductive layer CL1 contact each other does not include an interface where different materials contact each other. In some embodiments, the through conductive via TSV1 includes a lower portion TSV1b surrounded by the ring-shaped conductive via RV1 and the conductive layer CL1, and an upper portion TSV1a on the conductive layer CL1, wherein the width Wa of the upper portion TSV1a in the horizontal direction is greater than the width Wb of the lower portion TSV1b in the horizontal direction.

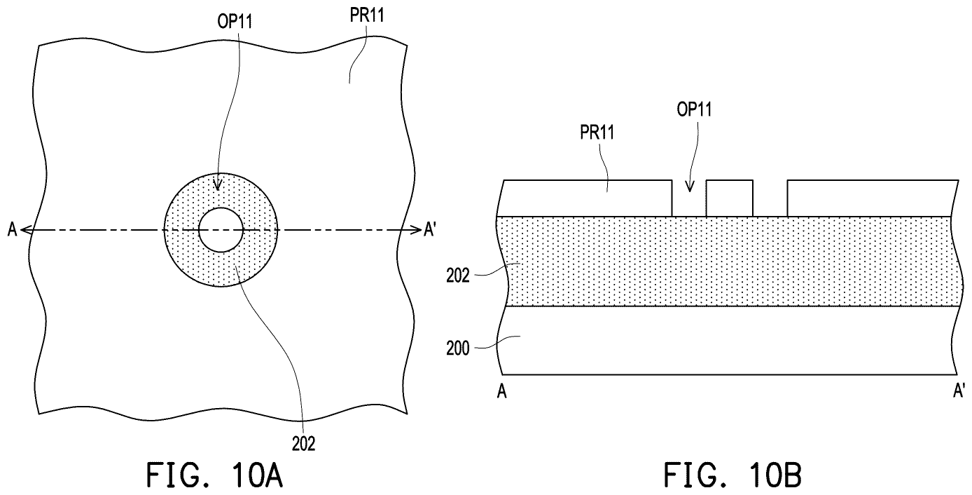

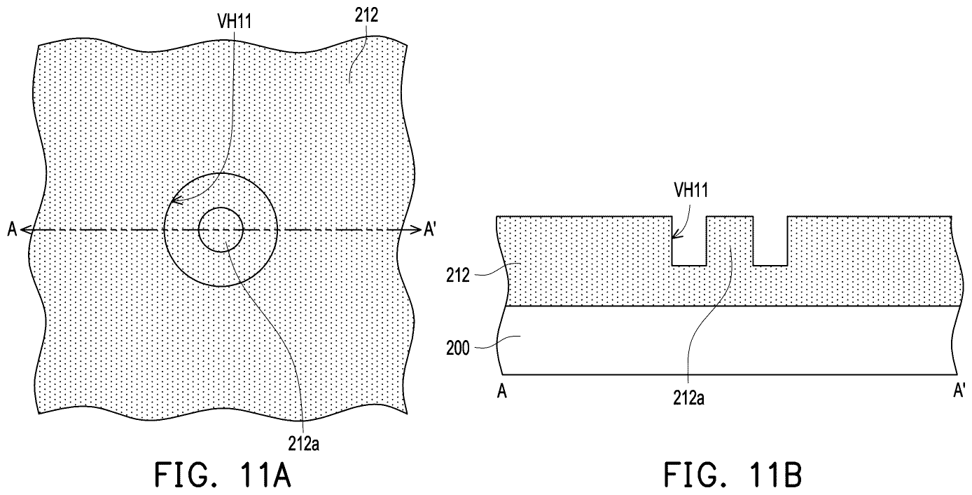

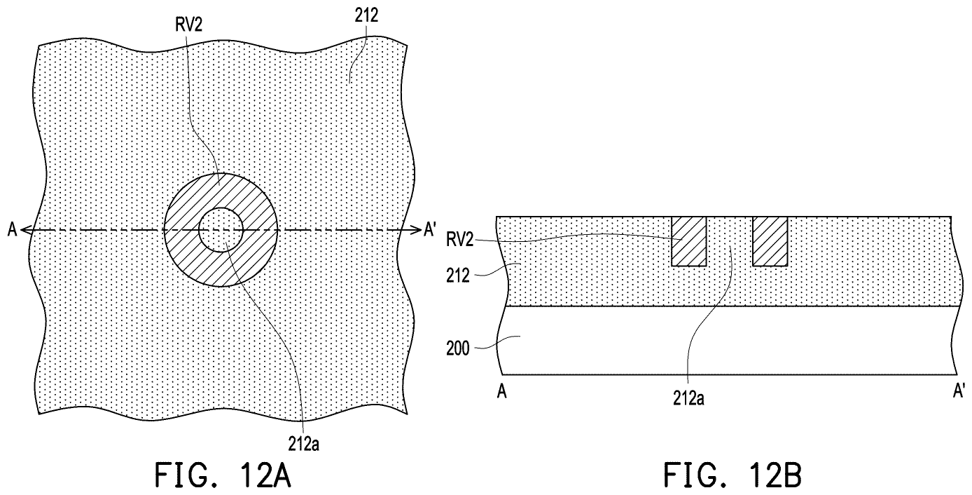

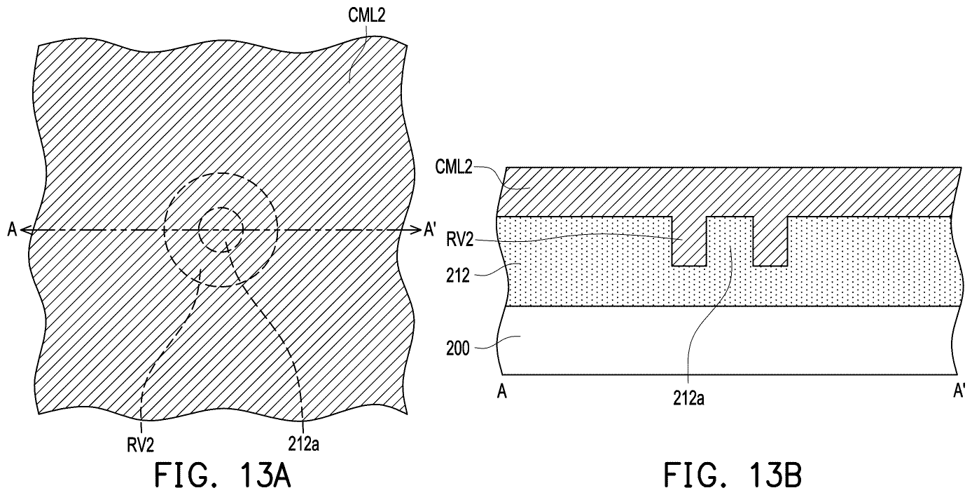

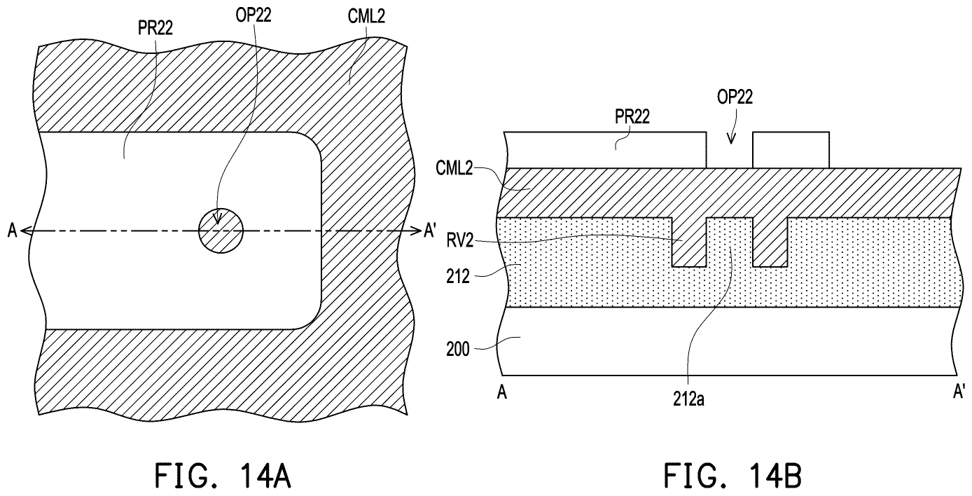

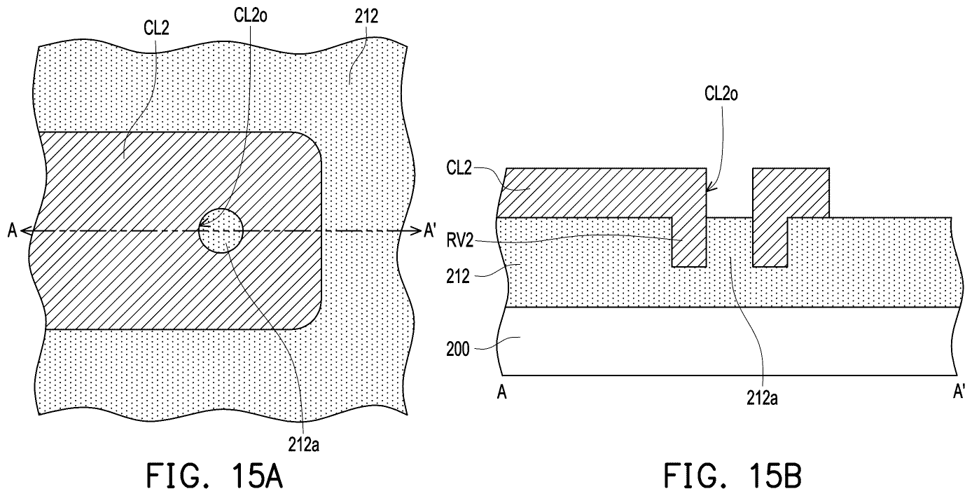

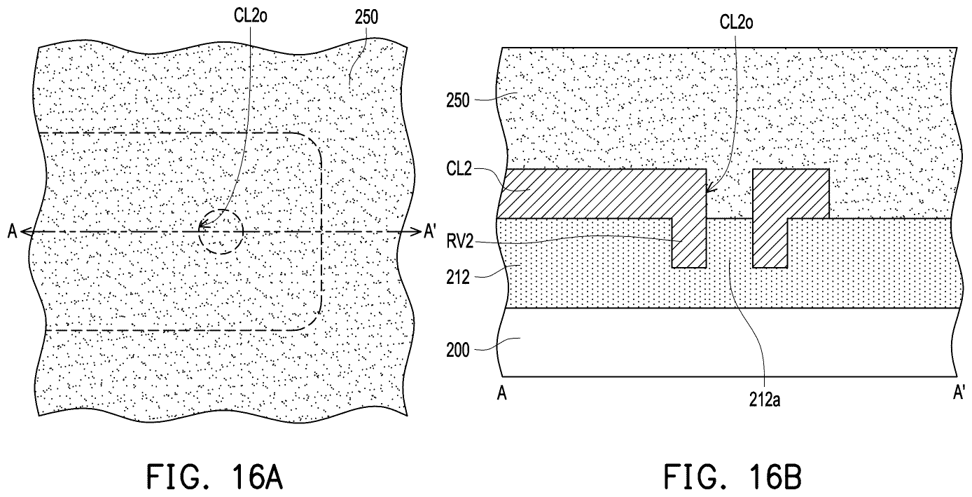

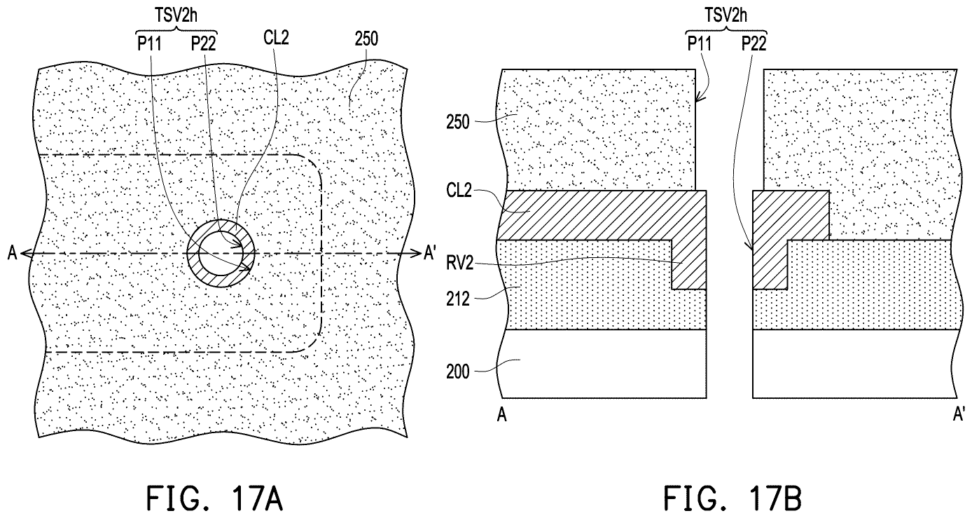

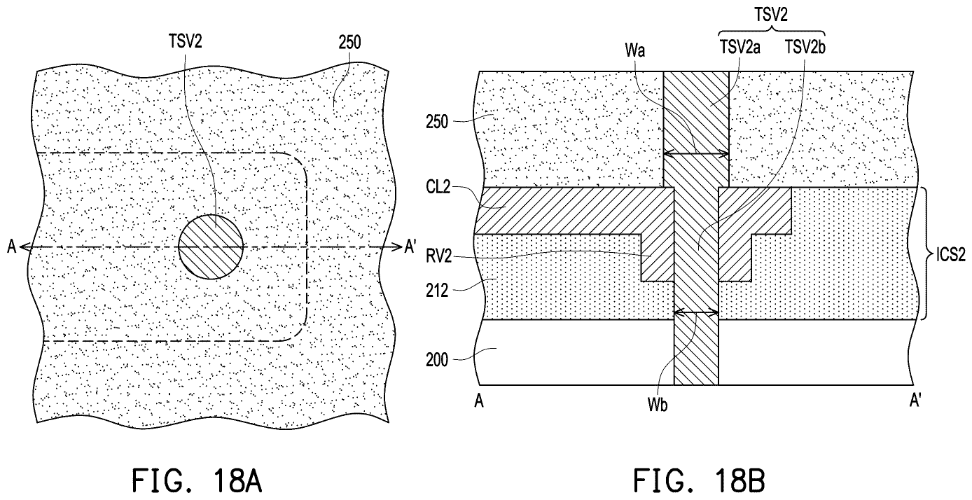

FIG. 10A to FIG. 18B are schematic cross-sectional views of a method for forming a semiconductor structure according to another embodiment of the present invention. FIG. 10A, FIG. 11A, FIG. 12A, FIG. 13A, FIG. 14A, FIG. 15A, FIG. 16A, FIG. 17A, and FIG. 18A are schematic top views of a method for forming a semiconductor structure according to another embodiment of the present invention, and FIG. 10B, FIG. 11B, FIG. 12B, FIG. 13B, FIG. 14B, FIG. 15B, FIG. 16B, FIG. 17B, and FIG. 18B are schematic cross-sectional views taken along line A-A′ in FIG. 10A, FIG. 11A, FIG. 12A, FIG. 13A, FIG. 14A, FIG. 15A, FIG. 16A, FIG. 17A, and FIG. 18A, respectively.

In some other embodiments, the conductive structure may be formed through the following steps, wherein the same or similar components as described in the above embodiments are represented by the same or similar reference numerals, and will not be repeated here.

Firstly, referring to FIG. 10A and FIG. 10B, a dielectric material layer 202 is formed on a substrate 200. The substrate 200 may include a semiconductor substrate or a semiconductor on insulator (SOI) substrate, and a device layer formed on the semiconductor substrate or the SOI substrate. The dielectric material layer 202 may include any suitable dielectric material.

Next, a ring via hole (e.g., the ring via hole VH11 shown in FIG. 11A and FIG. 11B) is formed in the dielectric material layer 202. In some embodiments, the ring via hole may be formed through the following steps. Firstly, referring to FIG. 10A and FIG. 10B, a mask pattern PR11 having a ring-shaped opening OP11 is formed on the dielectric material layer 202. Then, referring to FIG. 10A and FIG. 10B and FIG. 11A and FIG. 11B, a portion of the dielectric material layer 202 exposed by the ring-shaped opening OP11 is removed to form the dielectric material layer 212 and the ring via hole VH11. Afterwards, the mask pattern PR11 is removed after the ring via hole VH11 is formed.

Then, referring to FIG. 11A and FIG. 11B and FIG. 12A and FIG. 12B, a ring-shaped conductive via RV2 is formed in the ring via hole VH11. In some embodiments, the dielectric material layer 212 includes a portion 212a that is surrounded by the ring-shaped conductive via RV2.

Afterwards, referring to FIG. 12A and FIG. 12B and FIG. 13A and FIG. 13B, a conductive material layer CML2 covering the ring-shaped conductive via RV2 is formed on the dielectric material layer 212. In some embodiments, the conductive material layer CML2 may include conductive materials such as metals or metal alloys. The metals and metal alloys may be, for example, Cu, Al, Ti, Ta, W, Pt, Cr, Mo, or alloys thereof.

Then, the conductive material layer CML2 is patterned to form a conductive layer (e.g., the conductive layer CL2 shown in FIG. 15A and FIG. 15B). In some embodiments, the conductive layer may be formed through the following steps. Firstly, referring to FIG. 14A and FIG. 14B, a mask pattern PR22 is formed on the conductive material layer CML2. The mask pattern PR22 may include an opening OP22 that exposes a portion of the conductive material layer CML2. The portion of the conductive material layer CML2 may be located on a portion 212a of the dielectric material layer 212. In other words, the shape and location of the opening OP22 of the mask pattern PR22 may be corresponded to the shape and location of the portion 212a of the dielectric material layer 212 that is surrounded by the ring-shaped conductive via RV2. Next, referring to FIG. 14A and FIG. 14B and FIG. 15A and FIG. 15B, the portion of the conductive material layer CML2 exposed by the mask pattern PR22 is removed to form the conductive layer CL2. In this embodiment, the conductive layer CL2 may include an opening CL2o that exposes the portion 212a of the dielectric material layer 212 surrounded by the ring-shaped conductive via RV2.

Afterwards, referring to FIG. 15A and FIG. 15B and FIG. 16A and FIG. 16B, an insulation layer 250 is formed on the dielectric material layer 212, covering the conductive layer CL2 and filling the opening CL2o. In some embodiments, the insulation layer 250 may include oxide such as tetraethyl orthosilicate (TEOS), borophosphosilicate glass (BPSG), oxide formed by high-density plasma (HDP), undoped silicate glass (USG), phosphosilicate glass (PSG), oxide formed by spin-coating methods such as spin-on glass (SOG) and spin-on dielectric (SOD), or oxide formed by high aspect ratio process (HARP).

Then, referring to FIG. 16A and FIG. 16B and FIG. 17A and FIG. 17B, a through hole TSV2h is formed penetrating the insulation layer 250, the portion 212a of the dielectric material layer 212 surrounded by the ring-shaped conductive via RV2, and the substrate 200. The through hole TSV2h exposes the sidewall of the ring-shaped conductive via RV2. The through hole TSV2h may include a first portion P11 formed in the insulation layer 250 and a second portion P22 exposing the sidewall of the ring-shaped conductive via RV2. The second portion P22 of the through hole TSV2h is formed by removing the portion of the insulation layer 250 in the opening CL2o of the conductive layer CL2 and the portion 212a of the dielectric material layer 212 surrounded by the ring-shaped conductive via RV2 as well as the dielectric material layer 212 and substrate 200 thereunder.

After that, referring to FIG. 17A and FIG. 17B and FIG. 18A and FIG. 18B, a through conductive via TSV2 is formed in the through hole TSV2h. As a result, the through conductive via TSV2 penetrates the substrate 200 and the interconnection structure ICS2 in the vertical direction, and the ring-shaped conductive via RV2 is formed in the interconnection structure ICS2 and surrounds the through conductive via TSV2. This may increase the contact area between the through conductive via TSV2 and the conductive layer CL2 in the interconnection structure ICS2 through the ring-shaped conductive via RV2, thereby reducing the contact resistance and providing a promising stability. On the other hand, when the semiconductor structure is applied to a one-step TSV, the stability of the desired electrical connection path is ensured while the diameter and pitch of the one-step TSV are reduced. In some embodiments, the through conductive via TSV2 may include conductive materials such as metals or metal alloys. The metals and metal alloys may be, for example, Cu, Al, Ti, Ta, W, Pt, Cr, Mo, or alloys thereof. In some embodiments, the through conductive via TSV2 includes a lower portion TSV2b surrounded by the ring-shaped conductive via RV2 and the conductive layer CL2, and an upper portion TSV2a on the conductive layer CL2, where the width Wa of the upper portion TSV2a in the horizontal direction is greater than the width Wb of the lower portion TSV2b in the horizontal direction.

In summary, in the above-mentioned semiconductor structure and method for forming the same, the conductive structure is designed to include the through conductive via penetrating through the substrate and the interconnection structure in the vertical direction, and the ring-shaped conductive via disposed in the interconnection structure and surrounding the through conductive via. As such, the contact area between the through conductive via and the conductive layer in the interconnection structure can be increased through the ring-shaped conductive via, and thereby reducing the contact resistance and having a promising stability.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor structure, comprising:
a conductive structure penetrating through an interconnection structure and a substrate on which the interconnection structure is disposed, wherein the conductive structure comprises:
a through conductive via penetrating through the interconnection structure and the substrate in a vertical direction; and
a ring-shaped conductive via disposed in the interconnection structure and surrounding the through conductive via,
wherein the interconnection structure comprises a conductive layer configured on the ring-shaped conductive via and being directly in contact with a top surface of the ring-shaped conductive via.

2. The semiconductor structure according to claim 1, wherein a bottom surface of the ring-shaped conductive via is directly in contact with a dielectric layer in the interconnection structure.

3. The semiconductor structure according to claim 1, wherein the ring-shaped conductive via is directly in contact with the through conductive via.

4. The semiconductor structure according to claim 1, wherein the ring-shaped conductive via and the conductive layer are respectively a via portion and a wiring portion of an entire conductive layer.

5. The semiconductor structure according to claim 1, wherein the through conductive via comprises a lower portion surrounded by the ring-shaped conductive via and the conductive layer, and an upper portion on the conductive layer, wherein a width of the upper portion in a horizontal direction is greater than a width of the lower portion in the horizontal direction.

6. A method of forming a semiconductor structure, comprising:
forming a conductive structure, wherein the conductive structure penetrates through an interconnection structure and a substrate on which the interconnection structure is formed, and the conductive structure comprises:
a through conductive via penetrating through the substrate and the interconnection structure in a vertical direction; and
a ring-shaped conductive via formed in the interconnection structure and surrounding the through conductive via,
wherein the interconnection structure comprises a conductive layer formed on the ring-shaped conductive via and being directly in contact with a top surface of the ring-shaped conductive via.

7. The method according to claim 6, wherein a step of forming the ring-shaped conductive via comprises:
forming a stacked layer on the substrate, wherein the stacked layer comprises a plurality of first dielectric material layers and a plurality of second dielectric material layers that are stacked alternatively, and the second dielectric material layers are between the first dielectric material layers;
forming a ring via hole in the stacked layer, wherein the ring via hole penetrates through a first layer among the plurality of first dielectric material layers and a second layer among the plurality of first dielectric material layers and above the first layer;
forming a trench in the second layer communicating with the ring via hole; and
filling a conductive material into the ring via hole and the trench to form the ring-shaped conductive via and the conductive layer.

8. The method according to claim 7, wherein a step of forming the through conductive via comprises:
forming an insulation layer on the stacked layer after forming the ring-shaped conductive via;
forming a through hole penetrating the insulation layer, a portion of the stacked layer surrounded by the ring-shaped conductive via, and the substrate, wherein a sidewall of the ring-shaped conductive via is exposed by the through hole; and
forming the through conductive via in the through hole.

9. The method according to claim 6, wherein a step of forming the ring-shaped conductive via comprises:
forming a dielectric material layer on the substrate;
forming a ring via hole in the dielectric material layer; and
forming the ring-shaped conductive via in the ring via hole.

10. The method according to claim 9, wherein a step of forming the through conductive via comprises:
forming a conductive material layer covering the ring-shaped conductive via on the dielectric material layer;
patterning the conductive material layer to form the conductive layer, wherein the conductive layer comprises an opening exposing a portion of the dielectric material layer surrounded by the ring-shaped conductive via;
forming an insulation layer, covering the conductive layer and filling the opening, on the dielectric material layer;
forming a through hole penetrating the insulation layer, the portion of the dielectric material layer surrounded by the ring-shaped conductive via, and the substrate, wherein a sidewall of the ring-shaped conductive via is exposed by the through hole; and
forming the through conductive via in the through hole.
